(19) United States
(12) Patent Application Publication
(10) Pub. No.: US 2007/0117328 A1
(43) Pub. Date: May 24, 2007

(54) VERTICAL TRANSISTOR WITH FIELD REGION STRUCTURE

(76) Inventors: Chih-Feng Huang, Jhubei City (TW); Tuo-Hsin Chien, Tucheng City (TW); Jenn-yu G. Lin, Taipei (TW); Ta-yung Yang, Milpitas, CA (US)

Correspondence Address: J.C. Patents, Suite 250, 4 Venture, Irvine, CA, 92618, US

(21) Appl. No.: 11/622,429

(22) Filed: Jan. 11, 2007

Related U.S. Application Data
(62) Division of application No. 11/065,497, filed on Feb. 23, 2005.

(51) Int. Cl. H01L 21/336; H01L 29/94

(52) U.S. Cl. 438/268; 257/330

(57) ABSTRACT

A structure of a vertical transistor with field region is provided. The vertical transistor comprises a field-doping region formed in a substrate next to a core region of the vertical transistor By modulating the doping density, length, and geometrical pattern of the field region, and by connecting the field region to respective well of rim core regions of the vertical transistor, the present invention realizes a stable breakdown voltage with short length of the field region. Therefore, the device area and the manufacturing cost can be reduced.

### BACKGROUND OF THE INVENTION

1. Field of the Invention

The present invention relates to semiconductor devices, and more particularly, to a vertical transistor with field region.

2. Description of Related Art

Widely applied on vertical transistor manufacturing, a field region with floating ring structure can provide a breakdown voltage. A depletion region is formed between the field region and an epi layer to increase the breakdown voltage of the vertical transistor. In order to achieve a higher breakdown voltage, the length of the field region with floating ring structure is generally long, and thus a larger device area is required. This increases the manufacturing cost. Meanwhile, due to the floating ring structure of the field region, the electric field distribution is not uniform, which renders the breakdown voltage thereof unstable.

Therefore, an improved structure for vertical transistors is desired.

### SUMMARY OF THE INVENTION

One object of the present invention is to provide an improved structure for a vertical transistor.

According to the present invention, an improved structure comprises a field region surrounding the vertical transistor. The vertical transistor is composed of an array of core regions. The field region of the present invention is connected to respective well of the rim core regions of the vertical transistor, to provide a desired breakdown voltage with a shorter length, compared with the field region in floating ring structure.

Another object of the present invention is to provide an improved structure with uniform electric field distribution for vertical transistors.

According to the present invention, the field region connected to the respective well of the rim core regions is conducted to a voltage, i.e. source voltage. The doping density of the field region is adjustable. By two means thereof, it is able to uniform the electric field distribution across the field region and the epi layer, and thus provide a stable breakdown voltage.

### BRIEF DESCRIPTION OF THE DRAWINGS

These and other objects, features and advantages of the present invention will become apparent to those skilled in the art upon consideration of the following description of the embodiments of the present invention taken in conjunction with the accompanying drawings.

FIG. 1A shows a top view of a traditional structure of a vertical transistor.

FIG. 1B shows a top view of an improved structure of the vertical transistor according to one embodiment of the present invention.

FIG. 2 shows a cross-sectional view of the traditional structure of the vertical transistor.

FIG. 3 shows a cross-sectional view of the improved structure of the vertical transistor according to one embodiment of the present invention.

### DESCRIPTION OF THE PREFERRED EMBODIMENTS

The present invention provides an improved structure capable of ensuring a stable breakdown voltage and a desired breakdown voltage with shorter length of a field region, compared with the field region with floating ring structure.

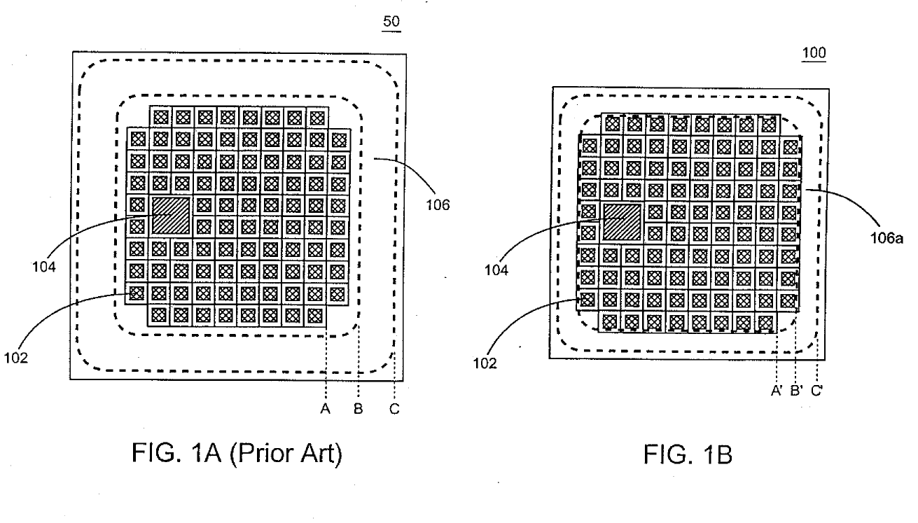

FIG. 1A shows a top view of a traditional structure of a vertical transistor 50. A field region 106 is applied to determine a breakdown voltage range of the vertical transistor 50.

FIG. 1B illustrates a top view of an improved structure of a vertical transistor 100 according to one embodiment of the present invention. The structure of the vertical transistor 100 comprises core regions 102, a gate pad 104 connected to respective gate of each core region 102, and a field region 106a. The field region 106a formed surrounding the core regions 102 is capable of increasing the breakdown voltage of the vertical transistor 100 by the depletion region formed between the field region 106a and an epi layer 206.

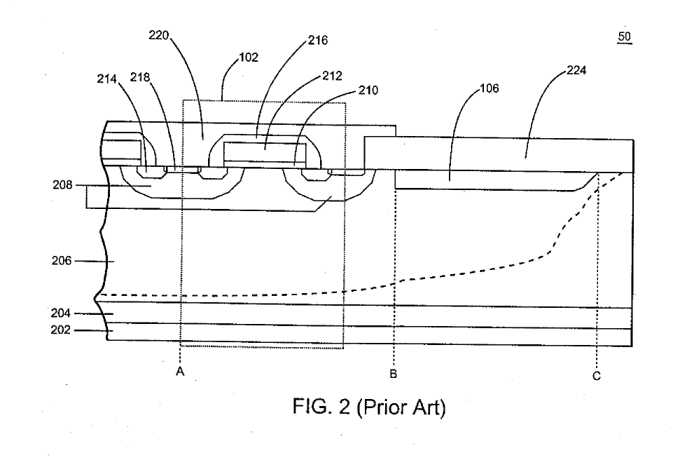

FIG. 2 shows the cross-sectional view of the traditional structure of the vertical transistor 50. Each core region 102 comprises a drain metal 202, a substrate 204, the epi layer 206, a well 208, a gate oxide 210, a gate layer 212, a first heavy doping region 214, a covered shell 216, a second heavy doping region 218, and a source metal 220.

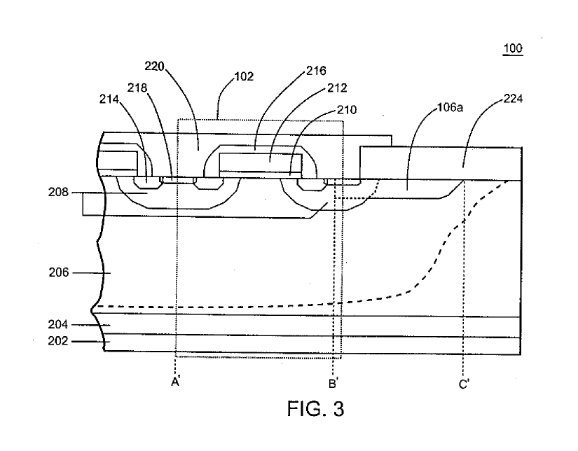

FIG. 3 shows the cross-sectional view of the improved structure of the vertical transistor 100 according to one embodiment of the present invention. The field oxide 224 is formed on the field region 106a. Unlike traditional structure of the vertical transistor 50, the field region 106a of the present invention is connected to a well 208, to thereby be conducted to a voltage, i.e. source voltage. By the applied voltage and adjustment of the doping density, the depletion region is fully depleted, and the across voltage is uniform, therefore a stable breakdown voltage can be provided. Meanwhile, the length of the field region 106a is shorter than the field region 106 in traditional structure of the vertical transistor 50, therefore the device area is reduced.

The present invention realizes a stable breakdown voltage and reduced device area by modulating the doping density, length, and geometrical pattern. of the field region 106a, and by connecting the field region 106a to the well 208.

1-2. (canceled)

3. A method for manufacturing a transistor, said method comprising steps of:
forming a field-doping region in a substrate;
forming a field oxide on said field-doping region;
forming a gate oxide on said substrate;
forming a gate layer on said gate oxide;
forming a well in said substrate;
forming a first heavy doping region in said well;
forming a covered shell over said gate oxide and said gate layer;
forming a second heavy doping region in said well next to said first heavy doping region;
forming a metal on said substrate as a electrode;
forming a backside metal on backside of said substrate as another electrode;

4. The method of claim 3, wherein the doping density of said field-doping region can be modulated for adjusting breakdown voltage.

5. The method of claim 3, wherein the length of said field-doping region can be modulated for adjusting breakdown voltage.

6. The method of claim 3, wherein the geometrical pattern of said field-doping region can be modulated for adjusting breakdown voltage.
